(19) United States
(12) Patent Application Publication
(10) Pub. No.: US 2023/0009651 A1
(43) Pub. Date: Jan. 12, 2023

(54) SYSTEMS AND METHODS FOR USING A TRANSFORMER TO ACHIEVE UNIFORMITY IN PROCESSING A SUBSTRATE

(71) Applicant: Lam Research Corporation, Fremont, CA (US)

(72) Inventors: Sunil Kapoor, Vancouver, WA (US); Dan Marohl, San Jose, CA (US); Shen Peng, Dublin, CA (US)

(21) Appl. No.: 17/780,011

(22) PCT Filed: Nov. 23, 2020
(86) PCT No.: PCT/US20/61874

§ 371 Date: May 25, 2022

Related U.S. Application Data
(60) Provisional application No. 62/944,323, filed on Dec. 5, 2019.

(51) Int. Cl. H01J 37/32; H03H 7/38; H01F 27/28

(52) U.S. Cl. CPC H01J 37/321; H01J 37/32183; H01J 37/32091; H03H 7/38; H01F 27/28; H01J 2237/327

(57) ABSTRACT

Systems and methods for using a transformer to achieve uniformity in processing a substrate are described. One of the systems includes a primary winding having a first end and a second end. The first end is coupled to an output of an impedance matching circuit and the second end is coupled to a capacitor. The system further includes a secondary winding associated with the primary winding and coupled to a first end and a second end of a transformer coupled plasma (TCP) coil of a plasma chamber. The primary winding receives a modified radio frequency (RF) signal from the impedance matching circuit to generate a magnetic flux to induce a voltage in the secondary winding. An RF signal generated by the voltage is transferred from the secondary winding to the TCP coil.

### FIELD

The embodiments described in the present disclosure relate to systems and methods for using a transformer to achieve uniformity in processing a substrate.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In a plasma tool, one or more radio frequency (RF) generators are coupled to an impedance matching network. The impedance matching network is coupled to a plasma chamber. RF signals are supplied from the RF generators to the impedance matching network. The impedance matching network outputs an RF signal upon receiving the RF signals. The RF signal is supplied from the impedance matching circuit to the plasma chamber for processing a wafer in the plasma chamber.

Due to various structures that are introduced in the plasma tool, inefficiencies in processing the wafer and additional wafers increase. For example, multiple wafers are not processed in a uniform manner. Also, there is a decrease in uniformity in a processing rate across each wafer.

It is in this context that embodiments described in the present disclosure arise.

### SUMMARY

Embodiments of the disclosure provide apparatus, systems, methods and computer programs for using a transformer to achieve uniformity in processing a substrate. It should be appreciated that the present embodiments can be implemented in numerous ways, e.g., a process, an apparatus, a system, a piece of hardware, or a method on a computer-readable medium. Several embodiments are described below.

A processing rate, such as an etch rate or a deposition rate, for processing a substrate is increased in a variety of ways. For example, an increase in radio frequency (RF) power that is supplied by an RF generator increases the processing rate. As another example, for the same power level, voltage and current ratio plays a role in deciding the processing rate. The voltage to current ratio can be modified by inserting a series capacitor or by using an interlaced dual coil antenna system. A series capacitor is sometimes referred to herein as a coil termination capacitor. An end of the series capacitor is coupled in series with a single antenna coil and another end of the series capacitor is grounded.

However, the series capacitor creates a resonance or a near resonance condition, which generates a high voltage across the single antenna coil. The high voltage reduces uniformity in processing the substrate. Also, there is a large drop in the voltage across the coil antenna when the end of the series capacitor is grounded. The large drop produces a tilt in voltage across the coil antenna and decreases the uniformity.

In case of the interlaced dual coil antenna system, multiple series capacitors are inserted. Each series capacitor is connected in series with a respective antenna coil of the interlaced dual coil antenna system. Again, because of the series capacitors, the same issues described above are present in case of the interlaced dual coil antenna system.

In one embodiment, a transformer-coupled inductively coupled plasma (ICP) system is used to increase the processing rate and is used to significantly increase uniformity. A transformer is used to change the voltage-to-current ratio for a given amount of power. The voltage-to-current ratio changes with a change in a primary and secondary winding ratio. The primary and secondary winding ratio is a ratio of a number of turns in a primary winding of the transformer to a number of turns in a secondary winding of the transformer. With the change in the primary and secondary winding ratio, the voltage-to-current ratio changes and the uniformity increases. The transformer can be used with both single and interlaced dual antenna coils.

In an embodiment, a transformer that works efficiently at high frequencies is described.

In an embodiment, a system for using a transformer to achieve uniformity in processing a substrate is described. The system includes a primary winding having a first end and a second end. The first end is coupled to an output of an impedance matching circuit and the second end is coupled to a capacitor. The system further includes a secondary winding associated with the primary winding and coupled to a first end and a second end of a transformer coupled plasma (TCP) coil of a plasma chamber. The primary winding receives a modified RF signal from the impedance matching circuit to generate a magnetic flux to induce a voltage in the secondary winding. An RF signal generated by the voltage is transferred from the secondary winding to the TCP coil.

In an embodiment, a transformer apparatus is described. The transformer apparatus includes a primary winding having a first end and a second end. The first end is coupled to an output of an impedance matching circuit and the second end is coupled to a capacitor. The transformer apparatus further includes a first secondary winding associated with the primary winding and coupled to a first end and a second end of a first TCP coil of a plasma chamber. The primary winding receives a modified RF signal from the impedance matching circuit to generate a magnetic flux to induce a voltage in the first secondary winding. An RF signal generated by the voltage induced in the first secondary winding is transferred via the first secondary winding to the first TCP coil. The transformer apparatus includes a second secondary winding associated with the primary winding and coupled to a first end and a second end of a second TCP coil of a plasma chamber. The magnetic field is configured to induce a voltage in the second secondary winding. An RF signal generated by the voltage induced in the second secondary winding is transferred from the second secondary winding to the second TCP coil.

In an embodiment, a method is described. The method includes receiving, by a primary winding of a transformer, a modified RF signal from an output of an impedance matching circuit. The primary winding is coupled to a capacitor. Upon receiving the modified RF signal, the method includes generating, by the primary winding, a magnetic flux to induce a voltage across a secondary winding of the transformer. The method includes transferring an RF signal generated by the voltage from the secondary winding to a TCP coil of a plasma chamber.

Some of the advantages of the systems and methods described herein include removing the coil termination capacitors. As explained above, the coil termination capacitors decrease the uniformity in the processing rate across a surface of the substrate. By removing the coil termination capacitors, the uniformity in the processing rate is increased.

Additional advantages of the herein described systems and methods include reducing voltage variation between endpoints of an antenna coil. The voltage variation can induce a tilt in the processing rate across the surface of the substrate. The voltage variation is reduced by connecting the transformer to a variable capacitor at each of its ends to control a voltage across the transformer. Also, the voltage variation is reduced by changing the primary and secondary winding ratio. The secondary winding is coupled in series to the antenna coil. A change in the primary and secondary winding ratio changes a voltage across the antenna coil to reduce the voltage variation between the endpoints of the antenna coil. The decrease in the voltage variation increases the uniformity in processing the substrate across a radius of the substrate.

A voltage across the antenna coil is the same as a voltage across the secondary winding when the second winding is coupled in series with the antenna coil, and there are no other components coupled to the secondary winding or the antenna coil. Voltage at both ends of the antenna coil can be controlled by changing the primary and secondary winding ratio, or by coupling the variable capacitors to the primary winding. The voltage at the ends of the antenna coil can be controlled to be approximately the same or the same. For example, the voltage at the ends of the antenna coil can be controlled to be within a pre-determined range from the same voltage. The approximately same or the same voltage increases the uniformity in processing the substrate.

Further advantages of the herein described systems and methods include eliminating or mitigating plasma beat frequency issues when the antenna coils and a pedestal are both applied the same RF frequency. The beat frequency undesirably modulates plasma within a plasma chamber. The transformer acts as an isolation transformer to eliminate or mitigate the plasma beat frequency issues.

Other aspects will become apparent from the following detailed description, taken in conjunction with the accompanying drawings.

### BRIEF DESCRIPTION OF THE DRAWINGS

The embodiments are understood by reference to the following description taken in conjunction with the accompanying drawings.

FIG. 1A is a diagram of an embodiment of a system to illustrate use of a transformer-based system for an inner coil of a transformer coupled plasma (TCP) chamber.

FIG. 1B is a diagram of an embodiment of a system to illustrate use of a transformer-based system for an outer coil of a TCP chamber.

FIG. 2 is a diagram of an embodiment of a system to illustrate use of a transformer-based system for both inner and outer coils of a TCP chamber.

FIG. 3 is a diagram of an embodiment of a system to illustrate transformers for interlaced inner TCP coils and for interlaced outer TCP coils.

FIG. 4A is a diagram of an embodiment of a transformer having a primary winding and multiple secondary windings.

FIG. 4B is a diagram of an embodiment of a transformer.

FIG. 4C is a diagram of an embodiment of a transformer to illustrate multiple taps on a secondary winding.

FIG. 4D is a diagram of an embodiment of a transformer to illustrate a twisting of primary and secondary windings of the transformer around each other.

FIG. 4E is a diagram of an embodiment of a transformer.

FIG. 5 is a diagram of an embodiment of a transformer to illustrate use of coaxial cables to fabricate the transformer.

FIG. 6A is a diagram of an embodiment of a system to illustrate use of a variable capacitor a instead of a fixed capacitor of the system of FIG. 1A.

FIG. 6B is a diagram of an embodiment of a system to illustrate use of a variable capacitor a instead of a fixed capacitor of the system of FIG. 1B.

FIG. 7 is a diagram of an embodiment of a system to illustrate use of the variable capacitors illustrated in FIGS. 6A and 6B with the system of FIG. 2.

FIG. 8 is a diagram of an embodiment of a system to illustrate use of the variable capacitors illustrated in FIGS. 6A and 6B with the system of FIG. 3.

FIG. 9 is a diagram of an embodiment of a system to illustrate a plasma tool in which a transformer-based system is used.

FIG. 10 is a diagram of an embodiment of a transformer to illustrate principles of the transformer.

### DETAILED DESCRIPTION

The following embodiments describe systems and methods for using a transformer to achieve uniformity in processing a substrate. It will be apparent that the present embodiments may be practiced without some or all of these specific details. In other instances, well known process operations have not been described in detail in order not to unnecessarily obscure the present embodiments.

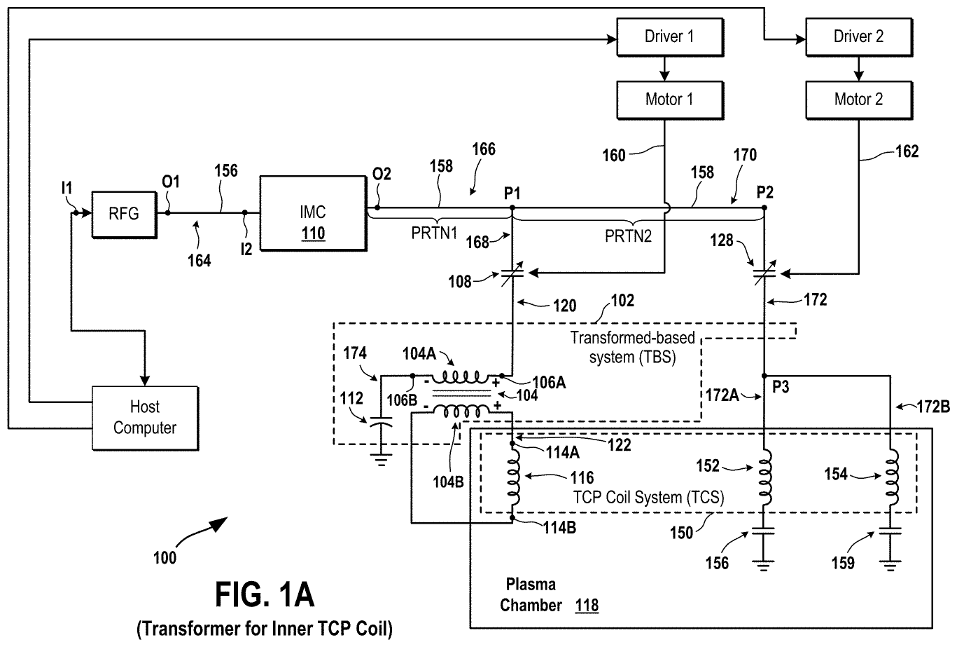

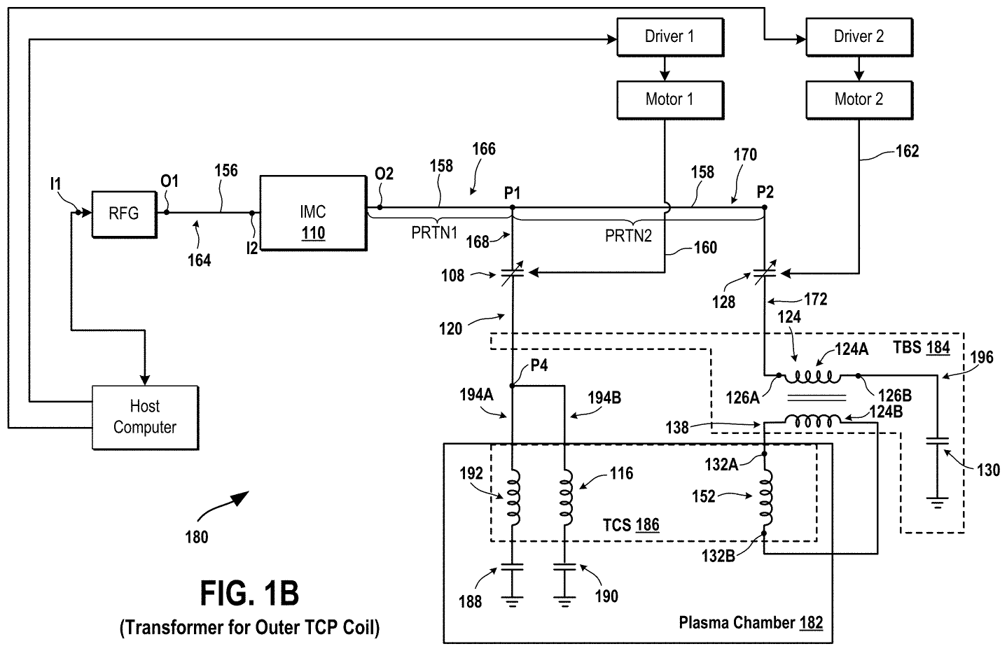

FIG. 1A is a diagram of an embodiment of a system 100 to illustrate use of a transformer-based system (TBS) 102 for an inner coil of a transformer coupled plasma (TCP) chamber 118. A TBS is sometimes referred to herein as a transformer apparatus. The system 100 includes a host computer, a radio frequency generator (RFG), an impedance matching circuit (IMC) 110, a driver 1, a motor 1, a driver 2, a motor 2, a connection mechanism 160, and a connection mechanism 162. The system 100 further includes the TBS 102 and the plasma chamber 118. The system 100 also includes a variable capacitor 108 and another variable capacitor 128.

Examples of the host computer include a desktop computer, a laptop computer, a controller, a tablet, and a smartphone. To illustrate, the host computer includes a processor and a memory device, and the processor is coupled to the memory device. Examples of the processor include a microprocessor, an application specific integrated circuit (ASIC), a programmable logic device (PLD), a microcontroller, and a central processing unit (CPU). Examples of the memory device include a read-only memory (ROM), a random access memory (RAM), a flash memory, a storage disk array, a hard disk, etc.

The RF generator has an operational frequency. For example, the RF generator is a 400 kilohertz (kHz), or a 2 megahertz (MHz), or a 27 MHz, or a 60 MHz RF generator. To illustrate, the RF generator includes an RF power supply, such as an RF oscillator, that oscillates to generate an RF signal having a frequency, such as 2 MHz or 27 MHz. The RF oscillator operates at the operational frequency, such as 2 MHz or 27 MHz, to generate the RF signal.

Examples of the impedance matching circuit 110 include a network of one or more series circuits and one or more shunt circuits, which are coupled to each other to facilitate a transfer of the RF signal received from the RF generator to output a modified RF signal. Examples of a series circuit include a capacitor, an inductor, and a resistor. Similarly, examples of a shunt circuit include a capacitor, an inductor, and a resistor.

Examples of a motor, as used herein, include an electric motor. Examples of the electric motor include an alternating current (AC) motor and a direct current (DC) motor. To illustrate, the electric motor includes a stator and a rotor, and the rotor rotates with respect to the stator. The electric motor is an electrical machine that converts electrical energy into mechanical energy, and operates through the interaction between the electric motor's magnetic field and an electric current in a wire winding of the stator to generate force in the form of rotation of a shaft that is attached to the rotor.

Examples of a driver, as used herein, includes one or more transistors that are coupled to each other for outputting a current signal when a voltage is applied at an input of the one or more transistors.

An example of a connection mechanism, as used herein, includes one or more shafts. Another example of a connection mechanism includes multiple shafts that are coupled to each other via one or more gears.

The TBS 102 includes a transformer 104 having a primary winding 104A and a secondary winding 104B. Examples of a transformer, as used herein, include a ferrite core transformer, which used for low frequency applications. For example, when the RF generator has an operating frequency of less than 1 MHz, the transformer is the ferrite core transformer. As another example, the transformer is a twisted-wire transformer, described below. The twisted wire transformed is used for high frequency applications. To illustrate, the twisted-wire transformer is used when the RF generator has an operating frequency of greater than 1 MHz. The TBS 102 further includes a capacitor 112, which is a fixed capacitor.

Moreover, the plasma chamber 118 includes a TCP coil system (TCS) 150, a coil-termination capacitor 156, and another coil-termination capacitor 159. The TCP coil system 150 includes a TCP coil 116, and multiple TCP coils 152 and 154.

The TCP coil 116 is an inner TCP coil and the TCP coils 152 and 154 are outer TCP coils. For example, a diameter of the inner TCP coil is smaller than a diameter of any of the outer TCP coils. As another example, the outer TCP coils surround the inner TCP coil. The outer TCP coils can surround the inner TCP coil at the same horizontal level as that of the inner TCP coil or at a different horizontal level than that of the inner TCP coil.

The RF transmission line 158 includes one or more RF rods, and each RF rod is surrounded an RF tunnel. As an example, the RF transmission line 158 includes multiple RF rods and any two of the RF rods are coupled to each other via an RF strap. An insulator material is provided between each RF rod and a corresponding RF tunnel that surrounds the RF rod to insulate the RF rod from the RF tunnel.

The host computer is coupled to an input I1 of the RF generator, to the driver 1 and to the driver 2. For example, the host computer is coupled via the input I1 and a data transfer cable to a digital signal processor (DSP) of the RF generator. The RF generator includes the DSP and the RF oscillator and the DSP is coupled to the RF oscillator. Examples of the transfer cable include a serial transfer cable for transferring data between the DSP and the RF generator in a serial manner, a parallel transfer cable for transferring the data in a parallel manner, and a Universal Serial Bus (USB) cable.

An output O1 of the RF generator is coupled to an input 12 of the IMC 110. For example, the output O1 of the RF oscillator is coupled via an RF cable 156 to the input 12 of the IMC 110. An output O2 of the IMC 110 is coupled via a portion PRTN1 of an RF transmission line 158 to the variable capacitor 108 and is coupled via another portion PRTN2 of the RF transmission line 158 to the variable capacitor 128. For example, the variable capacitor 108 is coupled to a point P1 on the RF rod of the RF transmission line 158 and the variable capacitor 128 is coupled to a point P2 on the RF rod of the RF transmission line 158.

The variable capacitor 108 is coupled via the connection mechanism 160 to the motor 1, which is coupled to the driver 1. An end of the variable capacitor 108 is coupled at the point P1 to the portion PRTN1 of the RF transmission line 158 and an opposite end of the variable capacitor 108 is coupled to an end 106A of the primary winding 104A. An opposite end 106B of the primary winding 104A is coupled to an end of the capacitor 112. An opposite end of the capacitor 112 is coupled to a ground connection at a ground potential, such as a zero potential.

An end of the secondary winding 104B is coupled to an end 114A of the TCP coil 116 and an opposite end of the secondary winding 104B is coupled to an opposite end 114B of the TCP coil 116. The TCP coil 116 and the secondary winding 104B are coupled to each other in series. For example, the end of the secondary winding 104B that is coupled to the end 114A has the same potential as the end 114A. Also, the opposite end of the secondary winding 104B that is coupled to the end 114B has the same potential as the end 114B. As another example, a voltage across the ends of the secondary winding 104B is the same as a voltage across the ends 114A and 114B of the TCP coil 116. It should be noted that there is no coil termination capacitor coupled in series to the TCP coil 116. For example, the coil termination capacitor is not coupled to the end 114B of the TCP coil 116.

The variable capacitor 128 is coupled via the connection mechanism 162 to the motor 2, which is coupled to the driver 2. An end of the variable capacitor 128 is coupled at the point P2 to the portion PRTN2 of the RF transmission line 158 and an opposite end of the variable capacitor 128 is coupled via a point P3 to ends of the TCP coils 152 and 154. An opposite end of the TCP coil 152 is coupled to an end of the coil-termination capacitor 156 and an opposite end of the TCP coil 154 is coupled to an end of the coil-termination capacitor 159. Opposite ends of the coil-termination capacitors 156 and 159 are coupled to the ground connection.

To operate the plasma system 100, the host computer generates and sends a control signal to the RF generator via the input I1. Upon receiving the control signal, the DSP of the RF generator controls the RF oscillator to generate an RF signal 164. The RF signal 164 is supplied via the output O1 of the RF generator and the RF cable 156 and the input 12 of the IMC 110 to the IMC 110. The IMC 110 receives the RF signal 164 and changes an impedance of the RF signal 164 to output a modified RF signal 166 at the output O2 of the IMC 110. For example, the series and shunt circuits of the IMC 110 change the impedance of the RF signal 164 to reduce RF power reflected towards the RF generator from the plasma chamber 118 via the RF transmission line 158.

The modified RF signal 166 is sent from the output O2 of the IMC 110 via the portion PRTN1 of the RF transmission line 158 to the point P1 and is split at the point P1 into a portion 168 and another portion 170. The portion 168 of the modified RF signal 166 is provided from the point P1 to the variable capacitor 108 and the portion 170 of the modified RF signal 168 is provided from the point P1 via the portion PRTN2 of the RF transmission line 158 and the point P2 to the variable capacitor 128. The portion 168 is referred to herein as a modified RF signal 168 and the portion 170 is referred to herein as a modified RF signal 170.

A capacitance of the variable capacitor 128 changes an impedance of the modified RF signal 170 to output a modified RF signal 172. The modified RF signal 172 is split at the point P3 into modified RF signals 172A and 172B. The modified RF signal 172A is provided from the point P3 to the TCP coil 152 and the modified RF signal 172B is provided from the point P3 to the TCP coil 154.

A capacitance of the variable capacitor 108 changes an impedance of the modified RF signal 168 to output a modified RF signal 120. The modified RF signal 120 is sent from the variable capacitor 108 and the end 106A of the primary winding 104A to the primary winding 104A. The modified RF signal 120 creates a voltage across the ends 106A and 106B of the primary winding 104A and passes via the primary winding 104A from the end 106A to the end 106B to generate a magnetic field having a magnetic flux. The magnetic flux is an amount the magnetic field passing through a unit surface area of a plane that is perpendicular to the magnetic field.

The magnetic field induces a voltage across the ends of the secondary winding 104B. The voltage induced across the ends of the secondary winding 104B generates an RF signal 122, such as an RF current signal, that flows from the end 114A of the TCP coil 116 to the end 114B of the TCP coil. When one or more process gases, described below, are applied to the plasma chamber 118 in addition to the application of the RF signal 122 to the TCP coil 116 and the modified RF signals 172A and 172B to the respective TCP coils 152 and 154, plasma is generated or maintained within the plasma chamber 118 to process a substrate, described below, within the plasma chamber 118.

An inductance of the primary winding 104A modifies an impedance of the modified RF signal 120 received at the end 106A to output a modified RF signal 174 at the end 106B of the primary winding 104A. The capacitor 112 receives the modified RF signal 174. Upon receiving the modified RF signal 174, the capacitor 112 has a capacitance that creates a voltage across the ends of the capacitor 112 and the voltage determines the voltage across the ends 106A and 106B of the primary winding 104A of the transformer 104.

Also, during operation of the plasma system 100, the host computer sends a capacitance control signal to the driver 1. The capacitance control signal is generated by the host computer to achieve a capacitance of the variable capacitor 108 and the capacitance corresponds to an amount of voltage to be achieved across the primary winding 104A and the amount of voltage corresponds to another amount of voltage to be achieved across the secondary winding 104B. The capacitance of the variable capacitor 108 and the amounts of voltages to be achieved across the primary and secondary windings 104A and 104B are stored in the memory device of the host computer. The processor of the host computer identifies the amount of capacitance of the variable capacitor 108 from the correspondence among the capacitance of the variable capacitor 108 and the amounts of voltages to be achieved across the primary and secondary windings 104A and 104B.

Upon receiving the capacitance control signal, the driver 1 generates a current signal that is sent to the motor 1. The motor 1 rotates to rotate, via the connection mechanism 160, a plate of the variable capacitor 108 with respect to an oppositely located plate of the variable capacitor 108 to achieve the capacitance within the capacitance control signal to further achieve the voltage across the primary winding 104A and the voltage across the secondary winding 104B.

Moreover, during operation of the plasma system 100, the host computer sends a capacitance control signal to the driver 2. The capacitance control signal is generated by the host computer to achieve a capacitance of the variable capacitor 128. Upon receiving the capacitance control signal, the driver 2 generates a current signal that is sent to the motor 2. The motor 2 rotates to rotate, via the connection mechanism 162, a plate of the variable capacitor 128 with respect to an oppositely located plate of the variable capacitor 128 to achieve the capacitance within the capacitance control signal.

In an embodiment, a capacitance of the variable capacitor 108 is not controlled during the operation of the plasma system 100. For example, during processing of the substrate, the capacitance of the variable capacitor 108 is fixed. As another example, instead of the variable capacitor 108, a fixed capacitor is used. Similarly, in an embodiment, a capacitance of the variable capacitor 128 is not controlled during the operation of the plasma system 100. For example, during processing of the substrate, the capacitance of the variable capacitor 128 is fixed. As another example, instead of the variable capacitor 128, a fixed capacitor is used.

In one embodiment, one or more of the variable capacitors 108 and 128 are not used in the plasma system 100. For example, the primary winding 104A is coupled to the point P1 on the RF transmission line 158 without being coupled to the variable capacitor 108. As another example, the TCP coils 152 and 154 are coupled to the RF transmission line 158 via the points P2 and P3 without being coupled to the variable capacitor 128.

FIG. 1B is a diagram of an embodiment of a system 180 to illustrate use of a TBS 184 for an outer coil of a transformer coupled plasma (TCP) chamber 182. The system 180 is the same in structure and function as the system 100 (FIG. 1A) except for a few differences between the systems 180 and 100. The differences between the systems 180 and 100 are described below.

The system 180 includes the host computer, the RF generator, the IMC 110, the driver 1, the motor 1, the driver 2, the motor 2, the connection mechanism 160, and the connection mechanism 162. The system 180 further includes the TBS 184 and the plasma chamber 182. The system 180 also includes the variable capacitors 108 and 128.

The TBS 184 includes a transformer 124 having a primary winding 124A and a secondary winding 124B. The TBS 184 further includes a capacitor 130, which is a fixed capacitor. Moreover, the plasma chamber 182 includes a TCP coil system (TCS) 186, a coil-termination capacitor 188, and another coil-termination capacitor 190. The TCP coil system 186 includes the TCP coils 116 and 152, and a TCP coil 192.

The TCPs coil 116 and 192 are inner TCP coils and the TCP coil 152 is an outer TCP coil. For example, a diameter of the inner TCP coils is smaller than a diameter of any of the outer TCP coil. As another example, the outer TCP coil surrounds the inner TCP coils. The outer TCP coil can surround the inner TCP coils at the same horizontal level as that of the inner TCP coils or at a different horizontal level than that of the inner TCP coils.

One end of the variable capacitor 108 is coupled at the point P1 to the portion PRTN1 of the RF transmission line 158 and the opposite end of the variable capacitor 108 is coupled via a point P4 to ends of the TCP coils 192 and 116. An opposite end of the TCP coil is coupled to an end of the coil-termination capacitor 188 and an opposite end of the TCP coil 116 is coupled to an end of the coil-termination capacitor 190. Opposite ends of the coil-termination capacitors 188 and 190 are coupled to the ground connection.

One end of the variable capacitor 128 is coupled at the point P2 to the portion PRTN2 of the RF transmission line 158 and an opposite end of the variable capacitor 128 is coupled to an end 126A of the primary winding 124A. An opposite end 126B of the primary winding 124A is coupled to an end of the capacitor 130. An opposite end of the capacitor 130 is coupled to the ground connection.

An end of the secondary winding 124B is coupled to an end 132A of the TCP coil 152 and an opposite end of the secondary winding 124B is coupled to an opposite end 132B of the TCP coil 152. The TCP coil 152 and the secondary winding 124B are coupled to each other in series. For example, the end of the secondary winding 124B that is coupled to the end 132A has the same potential as the end 132A. Also, the opposite end of the secondary winding 124B that is coupled to the end 132B has the same potential as the end 132B. As another example, a voltage across the ends of the secondary winding 124B is the same as a voltage across the ends 132A and 132B of the TCP coil 152. It should be noted that there is no coil termination capacitor coupled in series to the TCP coil 152. For example, the coil termination capacitor is not coupled to the end 132B of the TCP coil 152.

During operation of the plasma system 180, the modified RF signals 120 and 172 are generated in the same manner as that described above with reference to FIG. 1A. Moreover, the modified RF signal 120 is split at the point P4 into modified RF signals 194A and 194B. The modified RF signal 194A is provided from the point P4 to the TCP coil 192 and the modified RF signal 194B is provided from the point P4 to the TCP coil 116.

Also, the modified RF signal 172 is sent from the variable capacitor 128 and the end 126A of the primary winding 124A to the primary winding 124A. The modified RF signal 172 creates a voltage across the ends 126A and 126B of the primary winding 124A and passes via the primary winding 124A from the end 126A to the end 126B of the primary winding 124A to generate a magnetic field having a magnetic flux.

The magnetic field generated by the primary winding 124A induces a voltage across the ends of the secondary winding 124B. The voltage induced across the ends of the secondary winding 124B generates an RF signal 138, such as an RF current signal, that flows from the end 132A of the TCP coil 152 to the end 132B of the TCP coil 152. When one or more process gases are applied to the plasma chamber 182 in addition to the application of the RF signal 138 to the TCP coil 152 and the application of the modified RF signals 194A and 194B to the respective TCP coils 192 and 116, plasma is generated or maintained within the plasma chamber 182 to process a substrate within the plasma chamber 182.

An inductance of the primary winding 124A modifies an impedance of the modified RF signal 172 received at the end 126A to output a modified RF signal 196 at the end 126B of the primary winding 124A. The capacitor 130 receives the modified RF signal 196. Upon receiving the modified RF signal 196, the capacitor 130 has a capacitance that creates a voltage across the ends of the capacitor 130 and the voltage determines the voltage across the ends 126A and 126B of the primary winding 124A of the transformer 124.

Also, during operation of the plasma system 180, the host computer sends a capacitance control signal to the driver 2. The capacitance control signal is generated by the host computer to achieve a capacitance of the variable capacitor 128 and the capacitance corresponds to an amount of voltage to be achieved across the primary winding 124A and the amount of voltage corresponds to another amount of voltage to be achieved across the secondary winding 124B. The capacitance of the variable capacitor 128 and the amounts of voltages to be achieved across the primary and secondary windings 124A and 124B are stored in the memory device of the host computer. The processor of the host computer identifies the amount of capacitance of the variable capacitor 128 from the correspondence among the capacitance of the variable capacitor 128 and the amounts of voltages to be achieved across the primary and secondary windings 124A and 124B.

Upon receiving the capacitance control signal, the driver 2 generates a current signal that is sent to the motor 2. The motor 2 rotates to rotate the plate of the variable capacitor 128 with respect to the oppositely located plate of the variable capacitor 128 to achieve the capacitance within the capacitance control signal to achieve the voltage across the primary winding 124A and the voltage across the secondary winding 124B.

Moreover, during operation of the plasma system 180, the host computer sends a capacitance control signal to the driver 1. The capacitance control signal is generated by the host computer to achieve a capacitance of the variable capacitor 108. Upon receiving the capacitance control signal, the driver 1 generates a current signal that is sent to the motor 1. The motor 1 rotates to rotate the plate of the variable capacitor 108 with respect to the oppositely located plate of the variable capacitor 108 to achieve the capacitance within the capacitance control signal.

In an embodiment, a capacitance of the variable capacitor 108 is not controlled during the operation of the plasma system 180. For example, during processing of the substrate, the capacitance of the variable capacitor 108 is fixed. As another example, instead of the variable capacitor 108, a fixed capacitor is used. Similarly, in an embodiment, a capacitance of the variable capacitor 128 is not controlled during the operation of the plasma system 180. For example, during processing of the substrate, the capacitance of the variable capacitor 128 is fixed. As another example, instead of the variable capacitor 128, a fixed capacitor is used.

In one embodiment, one or more of the variable capacitors 108 and 128 are not used in the plasma system 180. For example, the TCP coils 192 and 116 are coupled to the point P1 on the RF transmission line 158 via the point P4 without being coupled to the variable capacitor 108. As another example, the primary winding 124A is coupled to the point P2 on the RF transmission line 158 without being coupled to the variable capacitor 128.

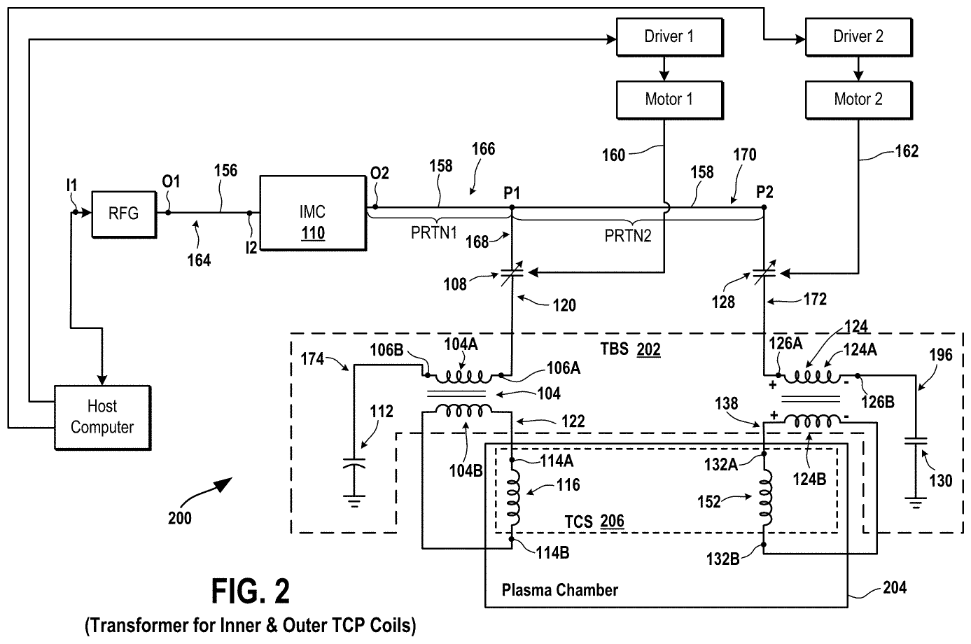

FIG. 2 is a diagram of an embodiment of a system 200 to illustrate use of a TBS 202 for both inner and outer coils of a transformer coupled plasma (TCP) chamber 204. The system 200 is a combination of a portion of the system 100 with a portion of the system 180 (FIGS. 1A and 1B). For example, the system 200 is the same in structure and function as the system 100 (FIG. 1A) except that differences between the systems 200 and 100 are described below. Also, the system 200 is the same in structure and function as the system 180 (FIG. 1B) except that differences between the systems 200 and 100 are described below.

The system 200 includes the host computer, the RF generator, the IMC 110, the driver 1, the motor 1, the driver 2, the motor 2, the connection mechanism 160, and the connection mechanism 162. The system 200 further includes the TBS 202 and the plasma chamber 204. The system 200 also includes the variable capacitors 108 and 128.

The TBS 202 includes the transformer 104 and the capacitor 112. The TBS 202 also includes the transformer 124 and the capacitor 130. Moreover, the plasma chamber 204 includes a TCP coil system (TCS) 206, which includes the TCP coils 116 and 152. The plasma chamber 204 excludes any coil-termination capacitors, such as the coil-termination capacitors 156, 159 (FIG. 1A), 188, and 190 (FIG. 1B).

The TCP coil 116 is an inner TCP coil and the TCP coil 152 is an outer TCP coil. For example, a diameter of the inner TCP coil is smaller than a diameter of the outer TCP coil. As another example, the outer TCP coil surrounds the inner TCP coil. The outer TCP coil can surround the inner TCP coil at the same horizontal level as that of the inner TCP coil or at a different horizontal level than that of the inner TCP coil.

One end of the variable capacitor 108 is coupled to the transformer 104 in the same manner as that described above with reference to FIG. 1A and the transformer 104 is coupled to the TCP coil 116 and the capacitor 112 in the same manner as that described above with reference to FIG. 1A. Moreover, one end of the variable capacitor 128 is coupled to the transformer 124 in the same manner as that described above with reference to FIG. 1B and the transformer 124 is coupled to the TCP coil 152 and the capacitor 130 in the same manner as that described above with reference to FIG. 1B.

The operation of the plasma system 200 is described above partly with reference to FIG. 1A and partly with reference to FIG. 1B. For example, the operation of the transformer 104, the variable capacitor 108, and the capacitor 112 is described with reference to FIG. 1A. Also, the operation of the transformer 124, the variable capacitor 128, and the capacitor 130 is described above with reference to FIG. 1B.

In one embodiment, one or more of the variable capacitors 108 and 128 are not used in the plasma system 200. For example, the primary winding 104A is coupled to the point P1 on the RF transmission line 158 without being coupled to the variable capacitor 108. As another example, the primary winding 124A is coupled to the point P2 on the RF transmission line 158 without being coupled to the variable capacitor 128.

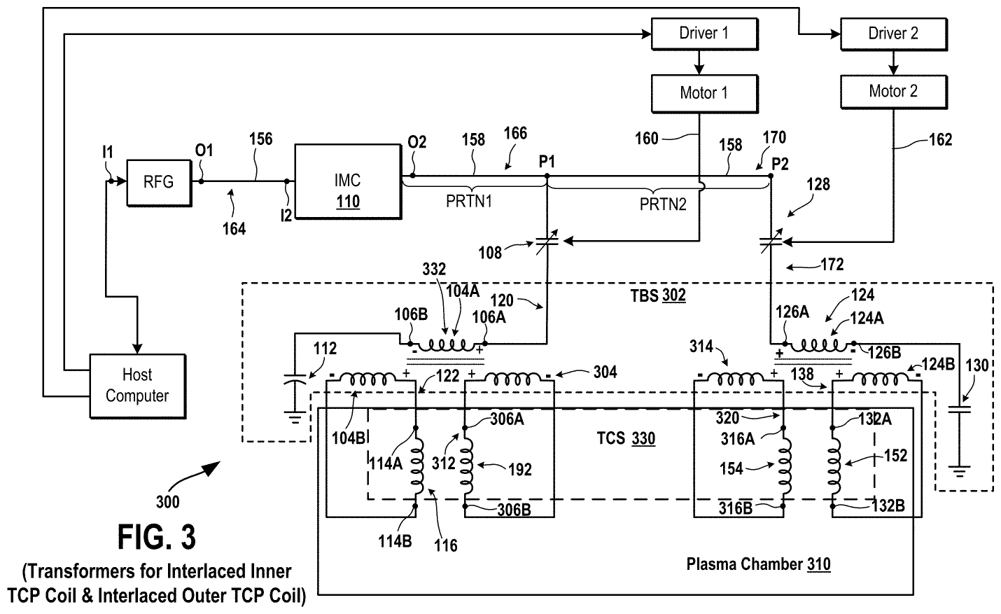

FIG. 3 is a diagram of an embodiment of a system 300 to illustrate transformers for interlaced inner TCP coils and for interlaced outer TCP coils. The system 300 is the same in structure and function as the system 200 (FIG. 2) except differences between the systems 300 and 200 are provided below. The system 300 includes the host computer, the RF generator, the IMC 110, the motor 1, the driver 1, the motor 2, and the driver 2. The system 300 further includes the variable capacitors 108 and 128, a transformer-based system 302, the connection mechanism 160, the connection mechanism 162, and a plasma chamber 310.

The TBS 302 includes a transformer 332 having the primary winding 104A, and multiple secondary windings 104B and 304. The TBS 302 further includes another transformer 334 having a primary winding 124A, and multiple secondary windings 124B and 314.

The plasma chamber 310 includes the TCP coil 116, the TCP coil 192, another TCP coil 152, and the TCP coil 154. The TCP coils 192 and 116 are inner TCP coils and the TCP coils 152 and 154 are outer TCP coils. For example, a diameter of any of the inner TCP coils is smaller than a diameter of any of the outer TCP coils. As another example, the outer TCP coils surround the inner TCP coils. The outer TCP coils can surround the inner TCP coils at the same horizontal level as that of the inner TCP coils or at a different horizontal level than that of the inner TCP coil.

One end of the secondary winding 304 of the transformer 332 is coupled to an end 306A of the TCP coil 192 and an opposite end of the secondary winding 304 is coupled to an opposite end 306B of the TCP coil 192. The TCP coil 192 and the secondary winding 304 are coupled to each other in series. For example, the end of the secondary winding 304 that is coupled to the end 306A has the same potential as the end 306A. Also, the opposite end of the secondary winding 304 that is coupled to the end 306B has the same potential as the end 306B. As another example, a voltage across the ends of the secondary winding 304 is the same as a voltage across the ends 306A and 306B of the TCP coil 192. It should be noted that there is no coil termination capacitor coupled in series to the TCP coil 192. For example, the coil termination capacitor is not coupled to the end 306B of the TCP coil 192.

Similarly, one end of the secondary winding 314 of the transformer 334 is coupled to an end 316A of the TCP coil 154 and an opposite end of the secondary winding 314 is coupled to an opposite end 316B of the TCP coil 154. For example, the end of the secondary winding 314 that is coupled to the end 316A has the same potential as the end 316A. Also, the opposite end of the secondary winding 314 that is coupled to the end 316B has the same potential as the end 316B. As another example, a voltage across the ends of the secondary winding 314 is the same as a voltage across the ends 316A and 316B of the TCP coil 154. It should be noted that there is no coil termination capacitor coupled in series to the TCP coil 154. For example, the coil termination capacitor is not coupled to the end 316B of the TCP coil 154.

During operation of the system 300, the modified RF signal 120 is output from the variable capacitor 108 in the same manner as that described above with reference to FIG. 1A. Also, the RF signal 122 is generated by the secondary winding 104B of the transformer 332 in the same manner as that described above with reference to FIG. 1A. The modified RF signal 120 creates the voltage across the ends 106A and 106B of the primary winding 104A and passes via the primary winding 104A from the end 106A to the end 106B of the primary winding 104A to generate a magnetic field having a magnetic flux. The magnetic field induces a voltage across the ends of the secondary winding 304. The voltage induced across the ends of the secondary winding 304 generates an RF signal 312, such as an RF current signal, that flows from the end 306A of the TCP coil 192 to the end 306B of the TCP coil 192.

Moreover, during operation of the system 300, the modified RF signal 172 is output from the variable capacitor 128 in the same manner as that described above with reference to FIG. 1B. Also, an RF signal 138 is generated by the secondary winding 124B of the transformer 334 in the same manner as that described above with reference to FIG. 1B.

The modified RF signal 172 creates the voltage across the ends 126A and 126B of the primary winding 124A and passes via the primary winding 124A from the end 126A to the end 126B of the primary winding 124A to generate the magnetic field having a magnetic flux. The magnetic field induces a voltage across the ends of the secondary winding 314. The voltage induced across the ends of the secondary winding 314 generates an RF signal 320, such as an RF current signal, that flows from the end 316A of the TCP coil 154 to the end 316B of the TCP coil 154.

When one or more process gases, described below, are applied to the plasma chamber 310 in addition to the RF signal 122 passing through the TCP coil 116, the RF signal 312 passing through the TCP coil 192, the RF signal 320 passing through the TCP coil 154, and the RF signal 138 passing through the TCP coil 152, plasma is generated or maintained within the plasma chamber 310 to process a substrate within the plasma chamber 310.

Also, during operation of the plasma system 300, the host computer sends a capacitance control signal to the driver 1. The capacitance control signal is generated by the host computer to achieve a capacitance of the variable capacitor 108 and the capacitance corresponds to an amount of voltage to be achieved across the primary winding 104A and the amount of voltage corresponds to another amount of voltage to be achieved across the secondary winding 104B and to yet another amount of voltage to be achieved across the secondary winding 304. The capacitance of the variable capacitor 108 and the amounts of voltages to be achieved across the primary winding 104A, the secondary winding 104B, and the secondary winding 304 are stored in the memory device of the host computer. The processor of the host computer identifies the amount of capacitance of the variable capacitor 108 from the correspondence among the capacitance of the variable capacitor 108 and the amounts of voltages to be achieved across the primary winding 104A, the secondary winding 104B, and the secondary winding 304.

Upon receiving the capacitance control signal, the driver 1 generates a current signal that is sent to the motor 1. The motor 1 rotates to rotate a plate of the variable capacitor 108 with respect to an oppositely located plate of the variable capacitor 108 to achieve the capacitance within the capacitance control signal to further achieve the voltage across the primary winding 104A, the voltage across the secondary winding 104B, and the voltage across the secondary winding 304.

Moreover, during operation of the plasma system 300, the host computer sends a capacitance control signal to the driver 2. The capacitance control signal is generated by the host computer to achieve a capacitance of the variable capacitor 128 and the capacitance corresponds to an amount of voltage to be achieved across the primary winding 124A and the amount of voltage corresponds to another amount of voltage to be achieved across the secondary winding 124B and to yet another amount of voltage to be achieved across the secondary winding 314. The capacitance of the variable capacitor 128 and the amounts of voltages to be achieved across the primary winding 124A, the secondary winding 124B, and the secondary winding 314 are stored in the memory device of the host computer. The processor of the host computer identifies the amount of capacitance of the variable capacitor 128 from the correspondence among the capacitance of the variable capacitor 128 and the amounts of voltages to be achieved across the primary winding 124A, the secondary winding 124B, and the secondary winding 314.

Upon receiving the capacitance control signal, the driver 2 generates a current signal that is sent to the motor 2. The motor 2 rotates to rotate a plate of the variable capacitor 128 with respect to an oppositely located plate of the variable capacitor 128 to achieve the capacitance within the capacitance control signal to further achieve the voltage across the primary winding 124A, the voltage across the secondary winding 124B, and the voltage across the secondary winging 314.

In an embodiment, in the same manner as that described above with reference to the plasma system 200 of FIG. 2, one or more of the variable capacitors 108 and 128 are not used in the plasma system 300.

Also, in an embodiment, one or more of the variable capacitors 108 and 128 are fixed, as described above with reference to the plasma system 200 of FIG. 2.

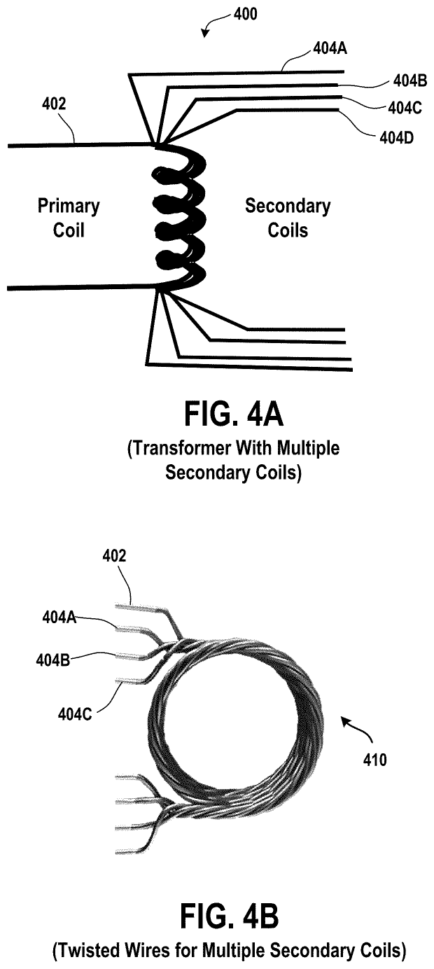

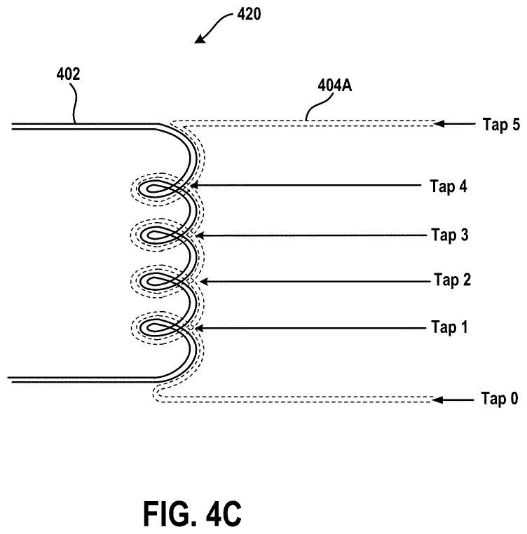

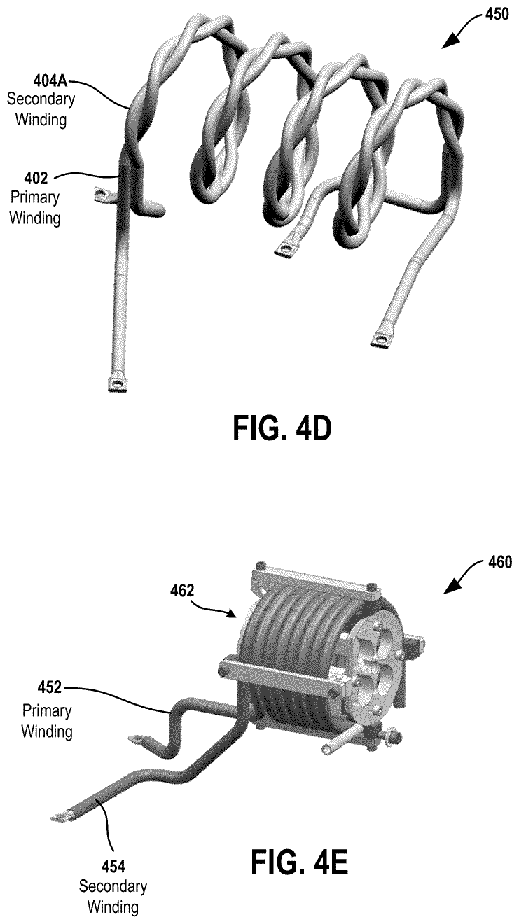

FIG. 4A is a diagram of an embodiment of a transformer 400 having a primary winding and multiple secondary windings. The transformer 400 includes a primary winding 402 and multiple secondary windings 404A, 404B, 404C, and 404D. The transformer 400 is an example of the twisted-wire transformer.

The primary winding 402 is an example of any of the primary windings 104A (FIGS. 1A and 2) and 124A (FIGS. 1B and 2). Any of the secondary windings 404A-404D is an example of any of the secondary windings 104B (FIG. 1A), 124B (FIG. 1B), 304 (FIG. 3), and 314 (FIG. 3).

The primary winding 402 and the secondary windings 404A-404D are twisted with respect to each other to fabricate the transformer 400. An example of the primary winding 402 is a metal wire with an insulator coating on the metal wire. To illustrate, the primary winding 402 is a copper wire or a magnetic wire coated with polyurethane. Similarly, an example of each of the secondary winding 404A-404D is a metal wire. To illustrate, each of the secondary winding 404A-404D is a copper wire having a coating of polyurethane.

In one embodiment, the transformer 400 includes more or less than four secondary windings. For example, the transformer 400 includes two secondary windings or five secondary windings. If the transformer 400 includes two of the secondary windings 404A-404D and the primary winding 402, the transformer 400 is an example of the transformer 332 or the transformer 334 (FIG. 3). If the transformer 400 includes one of the secondary windings 404A-404D and the primary winding 402, the transformer 400 is an example of the transformer 104 (FIG. 1A) or the transformer 124 (FIG. 1B).

In one embodiment, the primary winding 402 and the secondary windings 404A-404D are twisted around each other to form a braided structure.

FIG. 4B is a diagram of an embodiment of a transformer 410. The transformer 410 is another example of the twisted-wire transformer. The transformer 410 has the primary winding 402 and the secondary windings 404A, 404B, and 404C. The primary winding 402 and the secondary windings 404A-404C are twisted with respect to each other to fabricate the transformer 410.

It should be noted that there is no core material used for fabricating the transformer 410. The transformer 410 is an air core transformer. This facilitates use of the transformer 410 in the high frequency applications, described below. The high frequencies include microwave frequencies.

In one embodiment, the primary winding 402 and the secondary windings 404A, 404B, and 404C are twisted around each other to form a braided structure.

FIG. 4C is a diagram of an embodiment of a transformer 420 to illustrate multiple taps on a secondary winding. The transformer 420 is yet another example of the twisted-wire transformer. The transformer 420 has the primary winding 402 and the secondary winding 404A. As an example, the primary winding 402 and the secondary winding 404A are twisted around each other to fabricate the transformer 420. The secondary winding 404A has multiple taps, which include a tap 0, a tap 1, a tap 2, a tap 3, a tap 4, and a tap 5. As an example, a tap of a secondary winding is a contact, such as a wire connection, made at a position along the secondary winding.

As an example, the end 114A of the TCP coil 116 (FIGS. 1A, 2 and 3) is coupled to the tap 5 and the end 114B of the TCP coil 116 is coupled to the tap 0. As another example, the end 114A of the TCP coil 116 is coupled to the tap 4 and the end 114B of the TCP coil 116 is coupled to the tap 0. As yet another example, the end 114A of the TCP coil 116 is coupled to the tap 4 and the end 114B of the TCP coil 116 is coupled to the tap 1. As still another example, the end 114A of the TCP coil 116 is coupled to the tap 3 and the end 114B of the TCP coil 116 is coupled to the tap 1.

As another example, the end 306A of the TCP coil 192 (FIG. 3) is coupled to the tap 5 and the end 306B of the TCP coil 192 is coupled to the tap 0. As another example, the end 306A of the TCP coil 192 is coupled to the tap 4 and the end 306B of the TCP coil 192 is coupled to the tap 0. As yet another example, the end 306A of the TCP coil 192 is coupled to the tap 4 and the end 306B of the TCP coil 192 is coupled to the tap 1. As still another example, the end 306A of the TCP coil 192 is coupled to the tap 3 and the end 306B of the TCP coil 192 is coupled to the tap 1.

As yet another example, the end 316A of the TCP coil 154 (FIG. 3) is coupled to the tap 5 and the end 316B of the TCP coil 154 is coupled to the tap 0. As another example, the end 316A of the TCP coil 154 is coupled to the tap 4 and the end 316B of the TCP coil 154 is coupled to the tap 0. As yet another example, the end 316A of the TCP coil 154 is coupled to the tap 4 and the end 316B of the TCP coil 154 is coupled to the tap 1. As still another example, the end 316A of the TCP coil 154 is coupled to the tap 3 and the end 316B of the TCP coil 154 is coupled to the tap 1.

As still another example, the end 132A of the TCP coil 152 (FIGS. 1B, 2, and 3) is coupled to the tap 5 and the end 132B of the TCP coil 152 is coupled to the tap 0. As another example, the end 132A of the TCP coil 152 is coupled to the tap 4 and the end 132B of the TCP coil 152 is coupled to the tap 0. As yet another example, the end 132A of the TCP coil 152 is coupled to the tap 4 and the end 132B of the TCP coil 152 is coupled to the tap 1. As still another example, the end 132A of the TCP coil 152 is coupled to the tap 3 and the end 132B of the TCP coil 152 is coupled to the tap 1.

The change in the taps, for example, from the tap 1 to the tap 2 or the tap 2 to the tap 3, changes a voltage that is applied by the secondary winding 404A to a TCP coil that is coupled in series to the secondary winding 404A. For example, when the TCP coil is coupled to the secondary winding 404A via the taps 0 and 5, a different amount of voltage is applied to the TCP coil than when the TCP coil is coupled to the secondary winding 404A via the taps 1 and 3. As another example, when the TCP coil is coupled to the secondary winding 404A via the taps 1 and 2, a different amount of voltage is applied to the TCP coil than when the TCP coil is coupled to the secondary winding 404A via the taps 2 and 4.

In an embodiment, instead of six taps, the secondary winding 404A has a higher or a lower number of taps, such as three or seven.

In one embodiment, one or more of the secondary windings 404A-404D (FIG. 4A) has taps. For example, the secondary winding 404A has three taps, the secondary winding 404B has three taps, and the secondary winding 404C has three taps. As another example, instead of or in addition to connecting the taps 0 through 6 on the secondary winding 404A, the taps 0-6 are connected to the secondary winding 404B. As yet another example, instead of or in addition to connecting the taps 0 through 6 to the secondary winding 404A, the taps 0-6 are connected to any of the secondary windings 404C, 404D, and 404E.

In an embodiment, one or more of the secondary windings 404A-404D has a different number of taps than one or more of remaining of the secondary windings 404A-404D. For example, each of the secondary windings 404A and 404B has three taps and each of the secondary windings 404C and 404D has four taps.

FIG. 4D is a diagram of an embodiment of a transformer 450 to illustrate a twisting of primary and secondary windings of the transformer around each other. The transformer 450 includes the primary winding 402 and the secondary winding 404A. The primary winding 402 twists around the secondary winding 404A and the secondary winding 404A twists around the primary winding 402 to fabricate the transformer 450.

FIG. 4E is a diagram of an embodiment of a transformer 460. The transformer 460 includes a primary winding 452 and a secondary winding 454. Each of the primary winding 452 and the secondary winding 454 is a metal tube that is encased by an insulator. For example, the metal tube is made from copper. As another example, the metal tube is hollow and a space passes through a housing of the tube. The primary winding 452 and the secondary winding 454 are rolled in an interspersed manner with respect to each other. For example, the primary winding 452 is rolled on top of the secondary winding 454 and the secondary winding 454 is rolled on top of the primary winding 452 to alternate the primary winding 452 with the secondary winding 454 to fabricate the transformer. When the primary winding 452 and the secondary winding 454 are rolled in the interspersed manner, a cylinder 462 is formed that includes the primary winding 452 and the secondary winding 454.

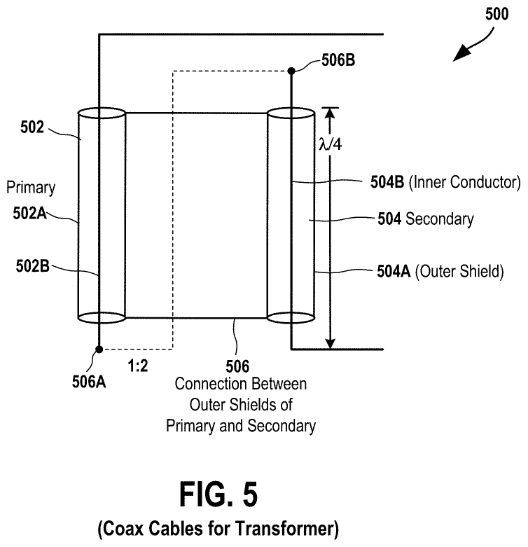

FIG. 5 is a diagram of an embodiment of a transformer 500 to illustrate use of coaxial cables to fabricate the transformer 500. The transformer 500 is used for high frequency applications. For example, the transformer 500 is used when the RF generator has an operating frequency of greater than 1 MHz.

The transformer 500 includes a primary winding 502 and a secondary winding 504. The primary winding 502 is an example of any of the primary windings 104A (FIG. 1A) and 124A (FIG. 2). The secondary winding 504 is an example of any of the secondary windings 104B (FIG. 1A), 124B (FIG. 1B), 304 (FIG. 3), and 314 (FIG. 3).

The primary winding 502 has an outer shield 502A and an inner conductor 502B. The outer shield 502B is made from an insulator and the inner conductor 502A is made from a metal, such as copper. The outer shield 502A encases, such as encloses, the inner conductor 502B along a length of the inner conductor 502B.

Similarly, the secondary winding 504 has an outer shield 504A and an inner conductor 504B. The outer shield 504B is made from an insulator and the inner conductor 504A is made from a metal, such as copper. Examples of an insulator, as described herein, include plastic polyvinyl chloride, polyethylene and polypropylene. The outer shield 504A encases, such as encloses, the inner conductor 504B along a length of the inner conductor 504B.

The primary winding 502 and the secondary winding 504 are connected to each other via a connection 506. For example, the primary winding 502 is placed adjacent to the secondary winding 504 and an insulator connects the primary winding 502 with the secondary winding 504.

The inner conductor 504B has a length that is twice a length of the inner conductor 502A to achieve a 1:2 ratio between the primary winding 502 and the secondary winding 504. The double length of the inner conductor 504B is illustrated by a dashed line between a point 506A on the inner conductor 502B and a point 506B on the inner conductor 504B. The dashed line is used to illustrate doubling of the length of the inner conductor 504B compared to the length of the inner conductor 502B. As another example, the inner conductor 504B has another length, such as three times or four times, the length of the inner conductor 502A.

As an example, a length of the secondary winding 504 is of a quarter wavelength, illustrated as λ/4. Other examples of the length of the secondary winding 504 include a length that is ½ wavelength or ⅕^{th} wavelength.

In one embodiment, a coaxial cable has a center metal conductor. The center conductor is encased along its length by a dielectric and the dielectric along its length by an outer metal conductor. The outer metal conductor is enclosed along its length by an insulator. An example of the center conductor is a copper wire. As an example, the dielectric is a plastic or a polyvinyl chloride. An example of the outer metal conductor is a metal mesh made from copper and an example of the insulator is plastic or polyvinyl chloride or polyethylene or polypropylene.

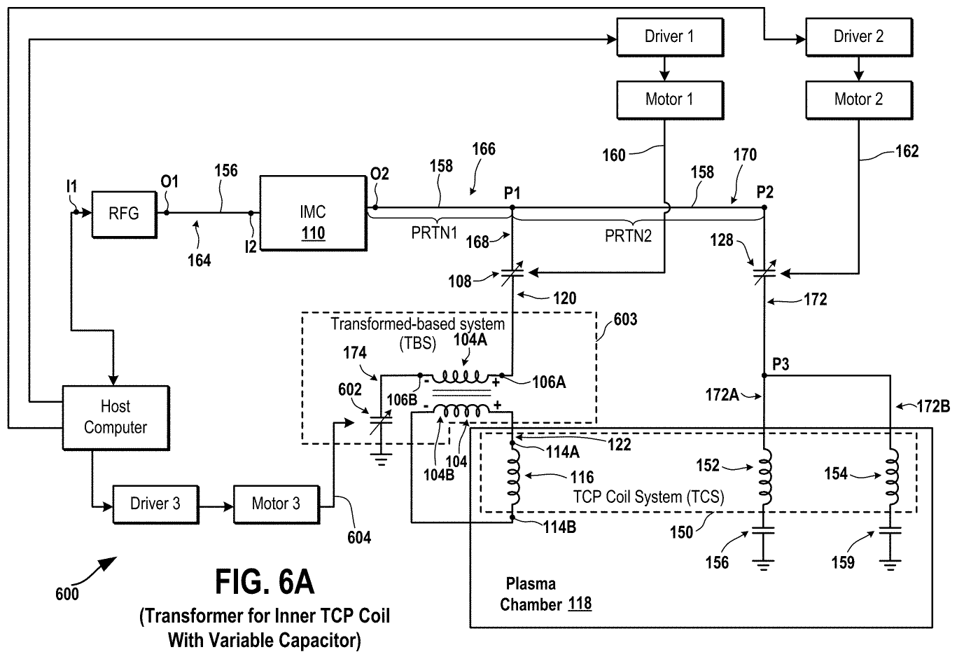

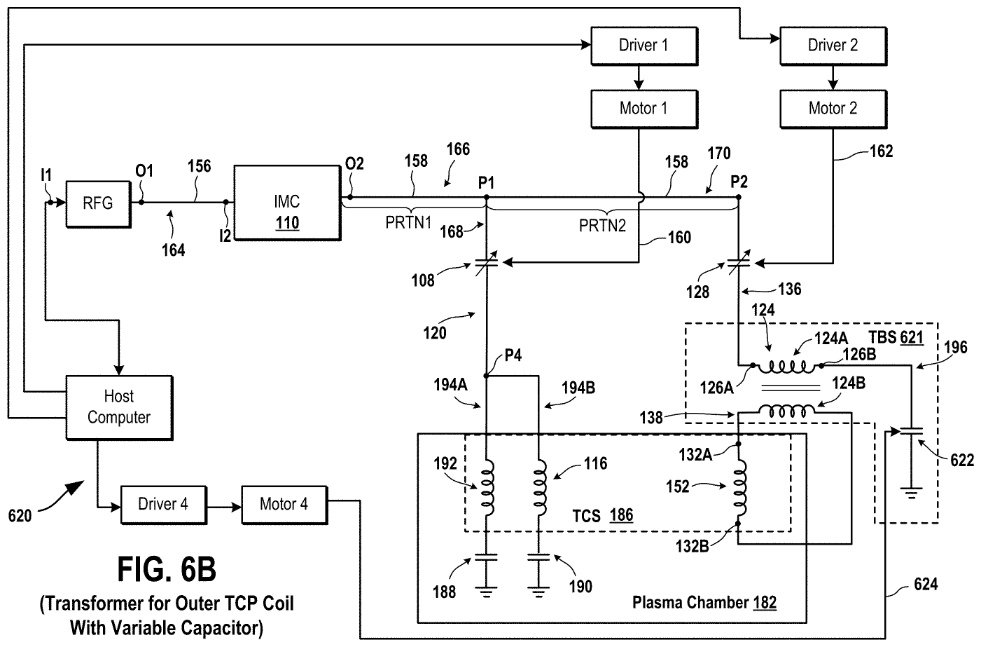

FIG. 6A is a diagram of an embodiment of a system 600 to illustrate use of a variable capacitor 602 instead of the capacitor 112 (FIG. 1A). The system 600 is the same, in structure and function, as the system 100 (FIG. 1A) except the system 600 has the variable capacitor 602 instead of the capacitor 112. For example, the system 600 includes a transformer-based system 603, which is the same in structure and function as the transformer-based system 102 (FIG. 1A), except that the transformer-based system 603 includes the variable capacitor 602 instead of the capacitor 112, which is fixed.

The system 600 further includes a driver 3, a motor 3, and a connection mechanism 604. The host computer is coupled to the driver 3 and the driver 3 is coupled to the motor 3. The motor 3 is coupled to the variable capacitor 602 via the connection mechanism 604.

During operation of the system 600, the host computer sends a capacitance control signal to the driver 3. The capacitance control signal is generated by the host computer to achieve a capacitance of the variable capacitor 602 and the capacitance corresponds to an amount of voltage to be achieved across the primary winding 104A and the amount of voltage corresponds to another amount of voltage to be achieved across the secondary winding 104B. The capacitance of the variable capacitor 108 and the amounts of voltages to be achieved across the primary and secondary windings 104A and 104B are stored in the memory device of the host computer. The processor of the host computer identifies the amount of capacitance of the variable capacitor 602 from the correspondence among the capacitance of the variable capacitor 602 and the amounts of voltages to be achieved across the primary and secondary windings 104A and 104B.

Upon receiving the capacitance control signal, the driver 3 generates a current signal that is sent to the motor 3. The motor 3 rotates to rotate, via the connection mechanism 604, a plate of the variable capacitor 602 with respect to an oppositely located plate of the variable capacitor 602 to achieve the capacitance within the capacitance control signal to further achieve the voltage across the primary winding 104A and the voltage across the secondary winding 104B. The voltage across the secondary winding 104B is achieved to generate the RF signal 122.

FIG. 6B is a diagram of an embodiment of a system 620 to illustrate use of a variable capacitor 622 instead of the capacitor 130 (FIG. 1B). The system 620 is the same, in structure and function, as the system 184 (FIG. 1B) except the system 620 has the variable capacitor 622 instead of the capacitor 130. For example, the system 620 includes a transformer-based system 621, which is the same in structure and function as the transformer-based system 184 (FIG. 1B), except that the transformer-based system 621 includes the variable capacitor 622 instead of the capacitor 130, which is fixed.

The system 620 further includes a driver 4, a motor 4, and a connection mechanism 624. The host computer is coupled to the driver 4 and the driver 4 is coupled to the motor 4. The motor 4 is coupled to the variable capacitor 622 via the connection mechanism 624.

During operation of the system 620, the host computer sends a capacitance control signal to the driver 4. The capacitance control signal is generated by the host computer to achieve a capacitance of the variable capacitor 622 and the capacitance corresponds to an amount of voltage to be achieved across the primary winding 124A and the amount of voltage corresponds to another amount of voltage to be achieved across the secondary winding 124B. The capacitance of the variable capacitor 622 and the amounts of voltages to be achieved across the primary and secondary windings 124A and 124B are stored in the memory device of the host computer. The processor of the host computer identifies the amount of capacitance of the variable capacitor 622 from the correspondence among the capacitance of the variable capacitor 622 and the amounts of voltages to be achieved across the primary and secondary windings 124A and 124B.

Upon receiving the capacitance control signal, the driver 4 generates a current signal that is sent to the motor 4. The motor 4 rotates to rotate, via the connection mechanism 624, a plate of the variable capacitor 622 with respect to an oppositely located plate of the variable capacitor 622 to achieve the capacitance within the capacitance control signal to further achieve the voltage across the primary winding 124A and the voltage across the secondary winding 124B. The voltage across the secondary winding 124B is achieved to generate the RF signal 196.

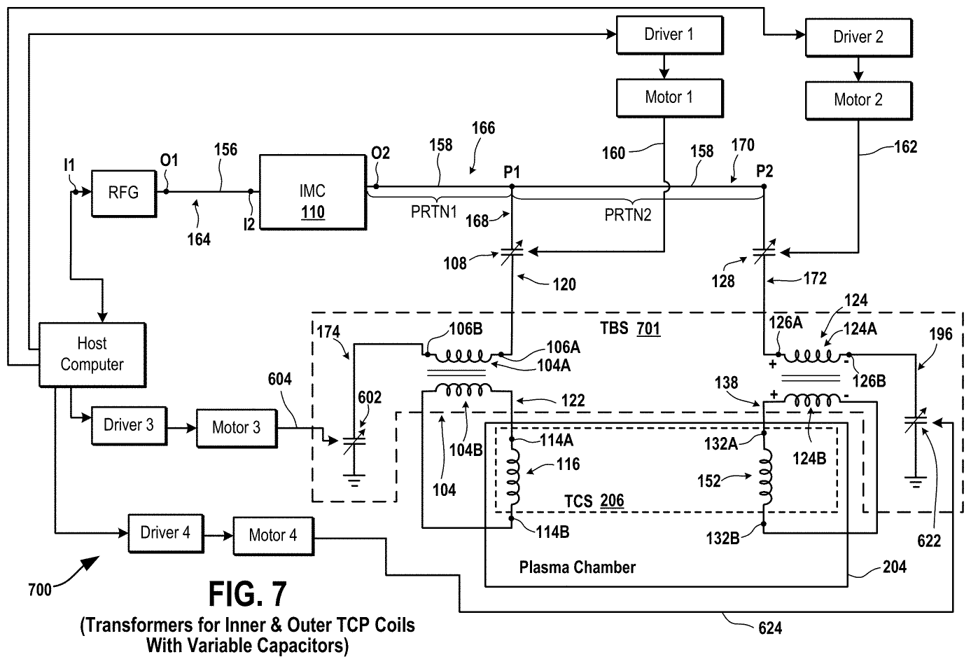

FIG. 7 is a diagram of an embodiment of a system 700 to illustrate use of the variable capacitor 602 instead of the capacitor 112 (FIG. 2) and use the variable capacitor 622 instead of the capacitor 130 (FIG. 2). The system 720 is the same, in structure and function, as the system 200 (FIG. 2) except the system 700 has the variable capacitor 602 instead of the capacitor 112 and the variable capacitor 622 instead of the capacitor 130. For example, the system 700 includes a transformer-based system 701, which is the same in structure and function as the transformer-based system 202 (FIG. 2), except that the transformer-based system 701 includes the variable capacitor 602 instead of the capacitor 112 and includes the variable capacitor 622 instead of the variable capacitor 130.

Also, the system 700 includes the drivers 3 and 4 and the motors 3 and 4. The operation of the driver 3 and the motor 3 is described above with reference to FIG. 6A and the operation of the driver 4 and the motor 4 is described above with reference to FIG. 6B. The voltage across the secondary winding 104B is achieved to generate the RF signal 174 and the voltage across the secondary winding 124B is achieved to generate the RF signal 196.

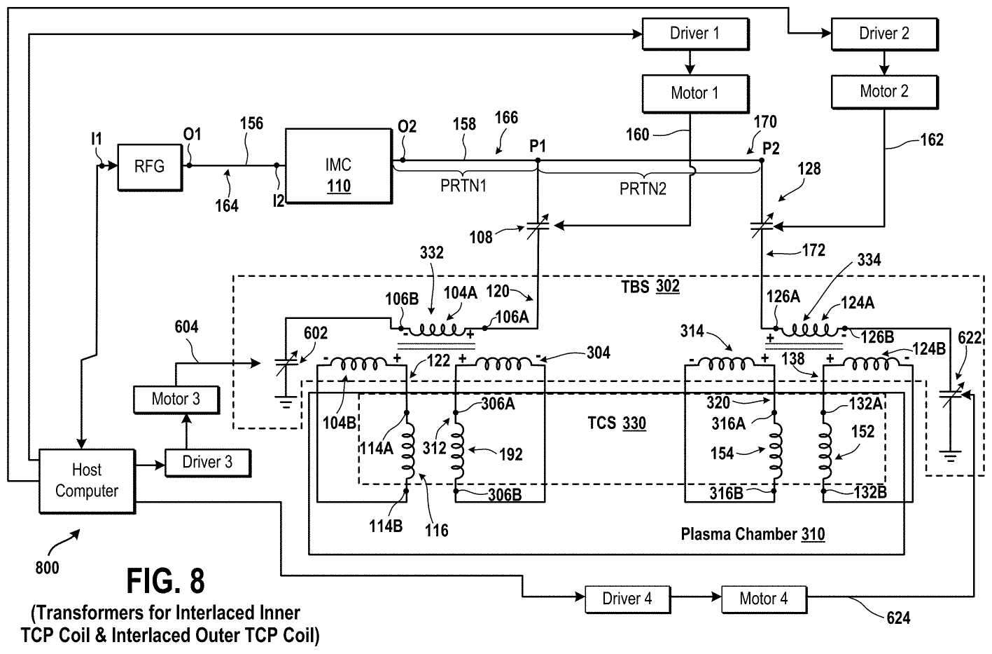

FIG. 8 is a diagram of an embodiment of a system 800 to illustrate use of the variable capacitor 602 instead of the capacitor 112 (FIG. 3) and use the variable capacitor 622 instead of the capacitor 130 (FIG. 3). The system 800 is the same, in structure and function, as the system 300 (FIG. 3) except the system 800 has the variable capacitor 602 instead of the capacitor 112 and the variable capacitor 622 instead of the capacitor 130. For example, the system 800 includes a transformer-based system 801, which is the same in structure and function as the transformer-based system 302 (FIG. 3), except that the transformer-based system 801 includes the variable capacitor 602 instead of the capacitor 112 and includes the variable capacitor 622 instead of the capacitor 130. Also, the system 800 includes the drivers 3 and 4 and the motors 3 and 4.

During operation of the system 800, the host computer sends a capacitance control signal to the driver 3. The capacitance control signal is generated by the host computer to achieve a capacitance of the variable capacitor 602 and the capacitance corresponds to an amount of voltage to be achieved across the primary winding 104A and the amount of voltage corresponds to another amount of voltage to be achieved across the secondary winding 104B. Also, the amount of voltage to be achieved across the primary winding 104A corresponds to another amount of voltage to be achieved across the secondary winding 304. The capacitance of the variable capacitor 602 and the amounts of voltages to be achieved across the primary winding 104A, the secondary winding 104B, and the secondary winding 304 are stored in the memory device of the host computer. The processor of the host computer identifies the amount of capacitance of the variable capacitor 602 from the correspondence among the capacitance of the variable capacitor 602 and the amounts of voltages to be achieved across the primary winding 104A, the secondary winding 104B, and the secondary winding 304.

Upon receiving the capacitance control signal, the driver 3 generates a current signal that is sent to the motor 3. The motor 3 rotates to rotate a plate of the variable capacitor 602 with respect to an oppositely located plate of the variable capacitor 602 to achieve the capacitance within the capacitance control signal to further achieve the voltage across the primary winding 104A, the voltage across the secondary winding 104B, and the voltage across the secondary winding 304. The voltage across the secondary winding 104B is achieved to generate the RF signal 122 and the voltage across the secondary winding 304 is achieved to generate the RF signal 312.

Moreover, during operation of the system 800, the host computer sends a capacitance control signal to the driver 4. The capacitance control signal is generated by the host computer to achieve a capacitance of the variable capacitor 622 and the capacitance corresponds to an amount of voltage to be achieved across the primary winding 124A and the amount of voltage corresponds to another amount of voltage to be achieved across the secondary winding 124B. Also, the amount of voltage to be achieved across the primary winding 124A corresponds to another amount of voltage to be achieved across the secondary winding 314. The capacitance of the variable capacitor 622 and the amounts of voltages to be achieved across the primary winding 124A, the secondary winding 124B, and the secondary winding 314 are stored in the memory device of the host computer. The processor of the host computer identifies the amount of capacitance of the variable capacitor 622 from the correspondence among the capacitance of the variable capacitor 622 and the amounts of voltages to be achieved across the primary winding 124A, the secondary winding 124B, and the secondary winding 314.

Upon receiving the capacitance control signal, the driver 4 generates a current signal that is sent to the motor 4. The motor 4 rotates to rotate a plate of the variable capacitor 622 with respect to an oppositely located plate of the variable capacitor 622 to achieve the capacitance within the capacitance control signal to further achieve the voltage across the primary winding 124A, the voltage across the secondary winding 124B, and the voltage across the secondary winding 314. The voltage across the secondary winding 124B is achieved to generate the RF signal 138 and the voltage across the secondary winding 314 is achieved to generate the RF signal 320.

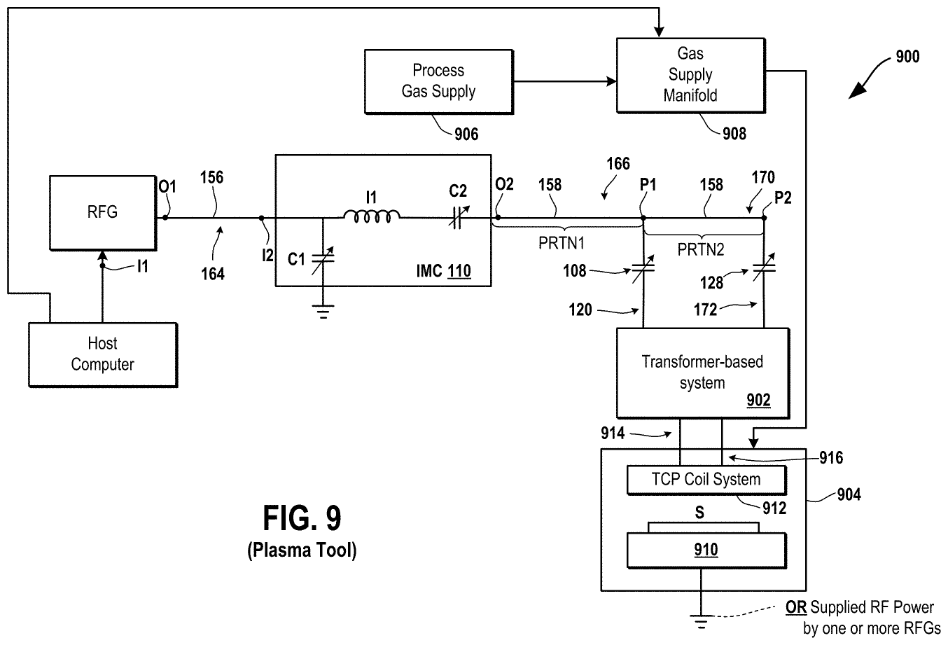

FIG. 9 is a diagram of an embodiment of a system 900 to illustrate a plasma tool in which a transformer-based system 902 is used. The system 900 includes the host computer, the RF generator, the IMC 110, the transformer-based system 902, a plasma chamber 904, a process gas supply 906, and a gas supply manifold 908.

The plasma chamber 904 includes a TCP coil system 912 and a substrate holder 910. The substrate holder 910 is coupled to the ground connection. The TCP coil system 912 is above the substrate holder 910. Examples of the TCP coil system 912 include the TCP coil system 150 (FIG. 1A), the TCP coil system 186 (FIG. 1B), the TCP coil system 206 (FIG. 2), and the TCP coil system 330 (FIG. 3).

Examples of the process gas supply 906 include one or more gas containers that store one or more process gases for processing a substrate S, such as a semiconductor wafer, placed on a substrate holder 910. An example of the substrate holder 910 includes a chuck. The chuck includes a lower electrode, which is coupled to the ground connection. Examples of the one or more process gases include an oxygen containing gas and a fluorine containing gas. The gas supply manifold 908 includes one or more valves for controlling, such as allowing or disallowing, a flow of the one or more process gases received from the process gas supply 906 via the gas supply manifold 908 to the plasma chamber 904 to achieve a pre-set mixture of process gases.

Examples of the transformer-based system 902 include the transformer-based system 102 (FIG. 1A), the transformer-based system 184 (FIG. 1B), the transformer-based system 202 (FIG. 2), the transformer-based system 302 (FIG. 3), the transformer-based system 603 (FIG. 6A), the transformer-based system 621 (FIG. 6B), the transformer-based system 701 (FIG. 7), and the transformer-based system 801 (FIG. 8). Examples of the TCP coil system 912 include the TCP coil system 150 (FIG. 1A), the TCP coil system 186 (FIG. 1B), the TCP coil system 206 (FIG. 2), and the TCP coil system 330 (FIG. 3).

The host computer is coupled to the RF generator, which is coupled to the IMC 110. The IMC 110 is coupled to the RF transmission line 158. The host computer is coupled to the process gas supply 906, which is coupled to the gas supply manifold 908, which is coupled to the plasma chamber 904. The IMC 110 is coupled to the transformer-based system 902 via the RF transmission line 158. The variable capacitor 108 is coupled to the RF transmission line 158 and the variable capacitor 128 is coupled to the RF transmission line 158. The transformer-based system 902 is coupled to the variable capacitors 108 and 128 and is coupled to the TCP coil system 912.

During operation, in the same manner as that described above with reference to FIG. 1A, the modified RF signals 120 and 172 are generated. The transformer-based system 902 receives the modified RF signals 120 and 172 to output RF signal sets 914 and 916. An example of the RF signal set 914 includes the RF signal 122 (FIGS. 1A and 2), or a set of the RF signals 194A and 194B (FIG. 1B), or a set of the RF signals 122 and 304 (FIG. 3). An example of the RF signal set 916 includes a set of the RF signals 172A and 172B (FIG. 1A), or the RF signal 138 (FIGS. 1B and 2), or a set of the RF signals 320 and 138 (FIG. 3).

Moreover, during operation, the host computer sends a control signal to the process gas supply 906 to supply the one or more process gases and sends a control signal to the gas supply manifold 908 to control amounts of the one or more process gases to the plasma chamber 904. When the one or more process gases are supplied to the plasma chamber 904 and the RF signals 914 and 916 are supplied to the TCP coil system 912, plasma is stricken or contained within the plasma chamber 904 to process the substrate S. Examples of processing the substrate S include etching the substrate S, depositing materials on the substrate S, sputtering the substrate S, and cleaning the substrate S.

In an embodiment, instead of being coupled to the ground connection, the substrate holder 910 is coupled to one or more RF generators via an impedance matching circuit. The one or more RF generators are coupled via respective one or more RF cables to the impedance matching circuit, which is coupled via an RF transmission line to the substrate holder 910. The one or more RF generators generate respective one or more RF signals, which are supplied via the respective one or more RF cables to the impedance matching circuit. The impedance matching circuit outputs a modified RF signal generated based on the one or more RF signals and sends the modified RF signal to the substrate holder 910 for processing the substrate S.

In an embodiment, a dielectric window is placed between the TCP coil system 912 and the substrate holder 910.

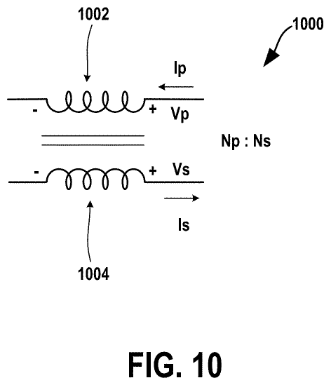

FIG. 10 is a diagram of an embodiment of a transformer 1000 to illustrate principles of the transformer 1000. The transformer 1000 is an example of the transformer 104 (FIG. 1A), or the transformer 124 (FIG. 1B). The transformer 1000 has a primary winding 1002 and a secondary winding 1004.

The transformer 1000 can be used to change a voltage-to-current ratio across the secondary winding 1004 for a given amount of power across the secondary winding 1004. The voltage-to-current ratio can be changed by varying a coil ratio Np/Ns between the primary winding 1002 and the secondary winding 1004. Np is a number of turns of the primary winding 1002 and Ns is a number of turns of the secondary winding 1004. A voltage across the primary winding 1002 is Vp and a voltage across the secondary winding 1004 is Vs. A current flowing through the primary winding is Ip and a current flowing through the secondary winding is Is. A transformer equation is provided below:

Vp/Vs=Is/Ip=Np/Ns (1)

A mutual inductance M between the primary winding 1002 and the secondary winding 1004 is expressed as:

M=k√(LpLs) (2)

where k is a coefficient of coupling between the primary winding 1002 and the secondary winding 1004, √ represents square root, Lp is an inductance of the primary winding 1002 and Ls is an inductance of the secondary winding 1004.

The twisted-wire transformer improves the coefficient of coupling between the primary winding 1002 and the secondary winding 1004. In the twisted-wire transformer, the primary winding 1002 is twisted with the secondary winding 1004. The coefficient of coupling k is dependent on a pitch of the primary winding 1002 and a pitch of the secondary winding 1002 of the twisted-wire transformer. For example, the pitch of each of the primary winding 1002 and the secondary winding 1004 can be defined so that the coefficient k is equal to 1 or approximately equal to 1, such as within a pre-defined range from 1. The coefficient of coupling is also dependent on parameters, such as resistive losses, of wires used for fabricating the primary winding 1002 and the secondary winding 1004. The twisting of the primary winding 1002 and the secondary winding 1004 with each other reduces differences in the coefficient of coupling k that is created by different wires of the primary winding 1002 and the secondary winding 1004.

Embodiments, described herein, may be practiced with various computer system configurations including hand-held hardware units, microprocessor systems, microprocessor-based or programmable consumer electronics, minicomputers, mainframe computers and the like. The embodiments, described herein, can also be practiced in distributed computing environments where tasks are performed by remote processing hardware units that are linked through a computer network.

In some embodiments, a controller is part of a system, which may be part of the above-described examples. The system includes semiconductor processing equipment, including a processing tool or tools, chamber or chambers, a platform or platforms for processing, and/or specific processing components (a wafer pedestal, a gas flow system, etc.). The system is integrated with electronics for controlling its operation before, during, and after processing of a semiconductor wafer or substrate. The electronics is referred to as the “controller,” which may control various components or subparts of the system. The controller, depending on processing requirements and/or a type of the system, is programmed to control any process disclosed herein, including a delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks connected to or interfaced with the system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSP)s, chips defined as ASICs, PLDs, one or more microprocessors, or microcontrollers that execute program instructions (e.g., software). The program instructions are instructions communicated to the controller in the form of various individual settings (or program files), defining operational parameters for carrying out a process on or for a semiconductor wafer. The operational parameters are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access for wafer processing. The controller enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to the system over a computer network, which includes a local network or the Internet. The remote computer includes a user interface that enables entry or programming of parameters and/or settings, which are then communicated to the system from the remote computer. In some examples, the controller receives instructions in the form of settings for processing a wafer. It should be understood that the settings are specific to a type of process to be performed on a wafer and a type of tool that the controller interfaces with or controls. Thus as described above, the controller is distributed, such as by including one or more discrete controllers that are networked together and working towards a common purpose, such as the fulfilling processes described herein. An example of a distributed controller for such purposes includes one or more integrated circuits on a chamber in communication with one or more integrated circuits located remotely (such as at a platform level or as part of a remote computer) that combine to control a process in a chamber.

Without limitation, in various embodiments, the system includes a plasma etch chamber, a deposition chamber, a spin-rinse chamber, a metal plating chamber, a clean chamber, a bevel edge etch chamber, a physical vapor deposition (PVD) chamber, a chemical vapor deposition (CVD) chamber, an atomic layer deposition (ALD) chamber, an atomic layer etch (ALE) chamber, an ion implantation chamber, a track chamber, and any other semiconductor processing chamber that is associated or used in fabrication and/or manufacturing of semiconductor wafers.

It is further noted that although the above-described operations are described with reference to an inductively coupled plasma (ICP) reactor, in some embodiments, the above-described operations apply to other types of plasma chambers, e.g., a plasma chamber including a parallel plate plasma chamber, a capacitively coupled plasma chamber, conductor tools, dielectric tools, a plasma chamber including an electron cyclotron resonance (ECR) reactor, etc.

As noted above, depending on a process operation to be performed by the tool, the controller communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These computer-implemented operations are those that manipulate physical quantities.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations, described herein, are performed by a computer selectively activated, or are configured by one or more computer programs stored in a computer memory, or are obtained over a computer network. When data is obtained over the computer network, the data may be processed by other computers on the computer network, e.g., a cloud of computing resources.

One or more embodiments, described herein, can also be fabricated as computer-readable code on a non-transitory computer-readable medium. The non-transitory computer-readable medium is any data storage hardware unit, e.g., a memory device, etc., that stores data, which is thereafter read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although some method operations, described above, were presented in a specific order, it should be understood that in various embodiments, other housekeeping operations are performed in between the method operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein, but may be modified within the scope and equivalents of the appended claims.

1. A transformer apparatus, comprising:
a primary winding having a first end and a second end, wherein the first end is coupled to an output of an impedance matching circuit and the second end is coupled to a capacitor;
a secondary winding associated with the primary winding and coupled to a first end and a second end of a transformer coupled plasma (TCP) coil of a plasma chamber,
wherein the primary winding is configured to receive a modified radio frequency (RF) signal from the impedance matching circuit to generate a magnetic flux to induce a voltage in the secondary winding, wherein an RF signal generated by the voltage is transferred from the secondary winding to the TCP coil.

2. The transformer apparatus of claim 1, wherein the TCP coil is in series with the secondary winding.

3. The transformer apparatus of claim 1, further comprising:
an additional primary winding having a first end and a second end, wherein the first end of the additional primary winding is coupled to the output of the impedance matching circuit and the second end of the additional primary winding is coupled to an additional capacitor;
an additional secondary winding associated with the additional primary winding and coupled to a first end and a second end of an additional TCP coil of the plasma chamber,
wherein the additional primary winding is configured to receive a modified RF signal from the impedance matching circuit to generate a magnetic flux to induce a voltage in the additional secondary winding, wherein an RF signal generated by the voltage induced in the additional secondary winding is transferred from the additional secondary winding to the additional TCP coil.

4. The transformer apparatus of claim 1, wherein the capacitor is coupled to a ground connection.

5. The transformer apparatus of claim 1, wherein the secondary winding is twisted with the primary winding to be associated with the primary winding.

6. The transformer apparatus of claim 1, wherein the secondary winding is rolled in an interspersed manner with the primary winding to be associated with the primary winding.

7. The transformer apparatus of claim 1, wherein the capacitor is a variable capacitor or a fixed capacitor.

8. The transformer apparatus of claim 1, wherein the capacitor is a variable capacitor that is coupled to a motor to change a capacitance of the variable capacitor.

9. The transformer apparatus of claim 1, wherein multiple taps are provided on the secondary winding to change the voltage that is applied by the secondary winding to the TCP coil.

10. The transformer apparatus of claim 1, wherein the first end of the primary winding is coupled via another capacitor to the impedance matching circuit, wherein the other capacitor is a fixed capacitor or a variable capacitor.

11. A transformer apparatus, comprising:
a primary winding having a first end and a second end, wherein the first end is coupled to an output of an impedance matching circuit and the second end is coupled to a capacitor;
a first secondary winding associated with the primary winding and coupled to a first end and a second end of a first transformer coupled plasma (TCP) coil of a plasma chamber,
wherein the primary winding is configured to receive a modified radio frequency (RF) signal from the impedance matching circuit to generate a magnetic flux to induce a voltage in the first secondary winding, wherein an RF signal generated by the voltage induced in the first secondary winding is transferred via the first secondary winding to the first TCP coil,
a second secondary winding associated with the primary winding and coupled to a first end and a second end of a second TCP coil of a plasma chamber,
wherein the magnetic field is configured to induce a voltage in the second secondary winding, wherein an RF signal generated by the voltage induced in the second secondary winding is transferred from the second secondary winding to the second TCP coil.

12. The transformer apparatus of claim 11, wherein the first TCP coil is in series with the first secondary winding and the second TCP coil is in series with the second secondary winding.

13. The transformer apparatus of claim 11, further comprising:
an additional primary winding having a first end and a second end, wherein the first end of the additional primary winding is coupled to the output of the impedance matching circuit and the second end of the additional primary winding is coupled to an additional capacitor;
an additional first secondary winding associated with the additional primary winding and coupled to a first end and a second end of a third TCP coil of the plasma chamber,
wherein the additional primary winding is configured to receive a modified RF signal from the impedance matching circuit to generate a magnetic flux to induce a voltage in the additional first secondary winding, wherein an RF signal generated by the voltage induced in the additional first secondary winding is transferred from the additional first secondary winding to the third TCP coil;
an additional second secondary winding associated with the additional primary winding and coupled to a first end and a second end of a fourth TCP coil of the plasma chamber,
wherein the magnetic flux generated by the additional primary winding induces a voltage in the additional second secondary winding, wherein an RF signal generated by the voltage induced in the additional second secondary winding is transferred from the additional second secondary winding to the fourth TCP coil.

14. The transformer apparatus of claim 11, wherein the capacitor is coupled to a ground connection.

15. The transformer apparatus of claim 11, wherein the capacitor is a variable capacitor or a fixed capacitor, wherein the variable capacitor is coupled to a motor to change a capacitance of the variable capacitor.

16. The transformer apparatus of claim 11, wherein the first secondary winding is twisted around the primary winding to be associated with the primary winding and the second secondary winding is twisted around the primary winding to be associated with the primary winding.

17. The transformer apparatus of claim 11, wherein the first secondary winding is rolled in an interspersed manner with the primary winding to be associated with the primary winding and the second secondary winding is rolled in an interspersed manner with the primary winding to be associated with the primary winding.

18. The transformer apparatus of claim 11, wherein the first end of the primary winding is coupled via another capacitor to the impedance matching circuit, wherein the other capacitor is a fixed capacitor or a variable capacitor.

19. A method comprising:
receiving, by a primary winding of a transformer, a modified radio frequency (RF) signal from an output of an impedance matching circuit, wherein the primary winding is coupled to a capacitor;
upon receiving the modified RF signal, generating, by the primary winding, a magnetic flux to induce a voltage across a secondary winding of the transformer; and
transferring an RF signal generated by the voltage from the secondary winding to a transformer coupled plasma (TCP) coil of a plasma chamber.

20. The method of claim 19, wherein the TCP coil is in series with the secondary winding.
